(19) United States
(12) Patent Application Publication
(10) Pub. No.: US 2016/0240733 A1
(43) Pub. Date: Aug. 18, 2016

(54) SEMICONDUCTOR LIGHT EMITTING DEVICE

(71) Applicants: Tae Young PARK, Yongin-si (KR); Sang Bum LEE, Hwaseong-si (KR); Pun Jae CHOI, Yongin-si (KR); Sung Joon KIM, Seoul (KR); Jin Wook CHUNG, Yongin-si (KR); Se Jun HAN, Suwon-si (KR); Su Min HWANGBO, Hwaseong-si (KR)

(72) Inventors: Tae Young PARK, Yongin-si (KR); Sang Bum LEE, Hwaseong-si (KR); Pun Jae CHOI, Yongin-si (KR); Sung Joon KIM, Seoul (KR); Jin Wook CHUNG, Yongin-si (KR); Se Jun HAN, Suwon-si (KR); Su Min HWANGBO, Hwaseong-si (KR)

(21) Appl. No.: 15/042,658

(22) Filed: Feb. 12, 2016

(30) Foreign Application Priority Data
Feb. 13, 2015 (KR) 10-2015-0022468

(51) Int. Cl. H01L 33/12; H01L 33/60; H01L 33/62; H01L 33/00; H01L 33/32

(52) U.S. Cl. CPC H01L 33/12; H01L 33/0008; H01L 33/32; H01L 33/62; H01L 33/60

(57) ABSTRACT

A semiconductor light emitting device is provided. The semiconductor light emitting device includes: a support substrate; a first layer disposed on the support substrate and applying tensile stress to the support substrate; a bonding layer disposed on the first layer; a second layer disposed on the bonding layer and applying compressive stress to the support substrate; and a light emitting structure disposed on the second layer and including a first conductivity-type semiconductor layer, an active layer, and a second conductivity-type semiconductor layer.

### CROSS-REFERENCE TO THE RELATED APPLICATION

This application claims priority from Korean Patent Application No. 10-2015-0022468 filed on Feb. 13, 2015 with the Korean Intellectual Property Office, the disclosure of which is incorporated herein in its entirety by reference.

### BACKGROUND

Apparatuses consistent with exemplary embodiments of the inventive concept relate to a semiconductor light emitting device, and more particularly, to a semiconductor light emitting device having improved light emitting efficiency without interrupting productivity during a manufacturing process thereof.

In general, semiconductor light emitting devices emit light as electrons recombine with electron holes when an electrical current is applied thereto. Semiconductor light emitting devices are widely used as light sources due to beneficial characteristics thereof such as relatively low power consumption, high levels of brightness, compact size, and the like. In particular, since the development of nitride-based light emitting devices, the use of semiconductor light emitting devices has significantly increased. Thus, semiconductor light emitting devices are used in a range of applications, such as backlight units for liquid crystal display (LCD) devices, home lighting devices, automotive lighting devices, and the like.

When a semiconductor light emitting structure of a semiconductor light emitting device is grown in a manufacturing process of semiconductor light emitting devices, stress may exist in the semiconductor light emitting structure, due to a difference in thermal expansion coefficients between the semiconductor light emitting structure and a growth substrate, or the like. Such stress may serve as an obstacle in the manufacturing process of semiconductor light emitting devices. Thus, a method of efficiently relieving the stress while improving the light emitting efficiency of semiconductor light emitting devices is required.

### SUMMARY

Exemplary embodiments of the inventive concept provide a structure of a semiconductor light emitting device in which light emitting efficiency may be improved as a level of a driving voltage is decreased.

According to an aspect of an exemplary embodiment, there is provided a semiconductor light emitting device which may include: a support substrate; a first layer disposed on the support substrate and applying tensile stress to the support substrate; a bonding layer disposed on the first layer and including compounds of a first bonding metal and a second bonding metal; a second layer disposed on the bonding layer and applying compressive stress to the support substrate; and a light emitting structure disposed on the second layer and including a first conductivity-type semiconductor layer, an active layer, and a second conductivity-type semiconductor layer.

A thermal expansion coefficient of the first layer may be greater than a thermal expansion coefficient of the support substrate.

The bonding layer may include a first bonding layer disposed adjacent to the first layer and a second bonding layer disposed adjacent to the second layer.

A thermal expansion coefficient of the second layer may be smaller than the thermal expansion coefficient of the first layer.

The first layer may contain at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, and alloys thereof.

The second layer may contain at least one selected from a group consisting of Ti, W, Ta, Ga, Si, alloys thereof, and nitrides thereof.

The first bonding metal may contain at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, Ti, and alloys thereof.

The second bonding metal may contain at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, Ti, and alloys thereof.

The support substrate may be a silicon substrate. The first layer may include Al, the first bonding layer and the second bonding layer may include Ti, and the second layer may include TiN.

A thickness of the first layer may range from 30 nm to 500 nm.

The thickness of the first layer may range from 50 nm to 200 nm.

A thickness of the second layer may range from 50 nm to 500 nm.

The thickness of the second layer may range from 200 nm to 300 nm.

The support substrate may be a silicon substrate.

The first conductivity-type semiconductor layer, the second conductivity-type semiconductor layer, and the active layer may be provided as group III nitride semiconductor layers.

According to an aspect of an exemplary embodiment, there is provided a semiconductor light emitting device which may include: a support substrate; a first layer disposed on the support substrate; a bonding layer disposed on the first layer and including a compound of at least two materials; a second layer disposed on the bonding layer; and a light emitting structure disposed on the second layer, wherein a thermal expansion coefficient of the first layer is greater than a thermal expansion coefficient of the support substrate. The semiconductor light emitting device may further include a first electrode, a second electrode and an insulation layer disposed between the first and second electrodes to insulate the first and second electrodes from each other, wherein the first and second electrodes and the insulation layer may be disposed between the second layer and the light emitting structure, and the insulation layer may include a reflect layer to reflect light emitted downwardly from the light emitting structure toward the light emitting structure. The insulation layer may include a plurality of layers having different refractive indices.

According to an aspect of an exemplary embodiment, there is provided a semiconductor light emitting device which may include: a support substrate, a first material layer disposed on the support substrate and having a thermal expansion coefficient greater than a thermal expansion coefficient of the support substrate; a bonding layer disposed on the first material layer; a second material layer disposed on the bonding layer and having a thermal expansion coefficient lower than the thermal expansion coefficient of the first material layer; and a light emitting structure disposed on the second material layer and including a first conductivity-type semiconductor layer, an active layer, and a second conductivity-type semiconductor layer.

### BRIEF DESCRIPTION OF THE DRAWINGS

The above and other aspects, features, and advantages of the inventive concept will be more clearly understood from the following detailed description taken in conjunction with the accompanying drawings, in which:

FIG. 1 is a cross-sectional view of a semiconductor light emitting device, according to an exemplary embodiment;

FIGS. 2A through 2D are schematic cross-sectional views illustrating a method of manufacturing a semiconductor light emitting device, according to an exemplary embodiment;

FIGS. 3A and 3B plan-view and cross-sectional view respectively, illustrating a semiconductor light emitting device according to an exemplary embodiment;

FIGS. 4 and 5 are cross-sectional views illustrating semiconductor light emitting device packages employing a semiconductor light emitting device according to an exemplary embodiment;

FIG. 6 is a cross-sectional view illustrating a semiconductor light emitting device according to an exemplary embodiment;

FIG. 7 is a graph comparing X-ray diffraction results of an exemplary embodiment of the inventive concept, a comparative example 1, and a comparative example 2;

FIG. 8 is a graph illustrating changes in current-voltage (I-V) of an exemplary embodiment of the inventive concept before and after annealing, and changes in current-voltage (IV) of a comparative example 2 before and after annealing;

FIG. 9 is a graph comparing the production yield rates of an exemplary embodiment of the inventive concept, a comparative example 2, and a comparative example 3;

FIGS. 10 and 11 are cross-sectional views schematically illustrating white light source modules having a semiconductor light emitting device according to an exemplary embodiment;

FIGS. 12A and 12B are views schematically illustrating a white light source module which may be adopted by a lighting device according to exemplary embodiments;

FIG. 13 is a (CIE) 1931 coordinate system provided to illustrate a wavelength conversion material which may be applied to a white light emitting device having a semiconductor light emitting device according to an exemplary embodiment;

FIG. 14 is a cross-sectional view schematically illustrating a structure of a quantum dot;

FIG. 15 is a perspective view schematically illustrating a backlight unit having a semiconductor light emitting device according to an exemplary embodiment;

FIG. 16 is a view illustrating a direct-type backlight unit according to an exemplary embodiment;

FIG. 17 is a view illustrating an example of an arrangement of light sources in a direct-type backlight unit according to an exemplary embodiment;

FIG. 18 is a view illustrating a direct-type backlight unit according to another exemplary embodiment;

FIG. 19 is a view illustrating a direct-type backlight unit according to still another exemplary embodiment;

FIG. 20 is an exploded perspective view schematically illustrating a bulb-type lamp as a lighting device having a semiconductor light emitting device according to an exemplary embodiment;

FIG. 21 is an exploded perspective view schematically illustrating a lamp including a communications module as a lighting device having a semiconductor light emitting device according to an exemplary embodiment; and

FIG. 22 is an exploded perspective view schematically illustrating a bar-type lamp as a lighting device having a semiconductor light emitting device according to an exemplary embodiment.

### DETAILED DESCRIPTION OF THE EXEMPLARY EMBODIMENTS

Exemplary embodiments of the inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will also be understood that when a layer is referred to as being “on” another layer or substrate, it can be directly on the other layer or substrate, or intervening layers may also be present. As used herein, the term “and/or” includes any and all combinations of one or more of the associated listed items and may be abbreviated as “/”.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

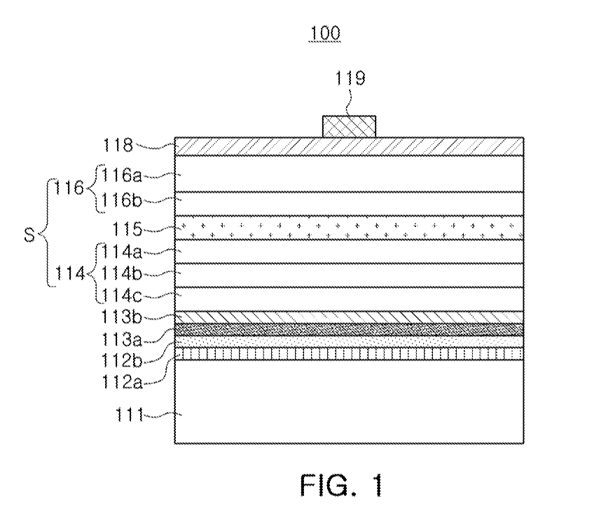

FIG. 1 is a cross-sectional view illustrating a semiconductor light emitting device according to an exemplary embodiment.

Referring to FIG. 1, a semiconductor light emitting device 100 may include a support substrate 111, a light emitting structure S, and a multilayer bonding structure joining the support substrate 111 and the light emitting structure S.

The semiconductor light emitting device 100 may include an ohmic contact layer 118 disposed on the light emitting structure S and an electrode layer 119 disposed on the ohmic contact layer 118, as an electrode. The support substrate 111 may be used as the other electrode. For example, the support substrate 111 may be a semiconductor substrate such as a silicon substrate, but is not limited thereto, and may be a conductive substrate.

The multilayer bonding structure may include a first layer 112a disposed on the support substrate 111, a first bonding layer 112b disposed on the first layer 112a, a second bonding layer 113a disposed on the first bonding layer 112b, and a second layer 113b disposed on the second bonding layer 113a.

The second layer 113b may apply compressive stress to the support substrate 111. In other words, the second layer 113b may relieve tensile stress of the support substrate 111. When a thermal expansion coefficient of the second layer 113b is smaller than a thermal expansion coefficient of the first layer 112a, the second layer 113b may relieve tensile stress applied to the support substrate 111 by the first layer 112a.

The second layer 113b may contain at least one selected from a group consisting of Ti, W, Ta, Ga, alloys thereof, and nitrides thereof. For example, the second layer 113b may be formed of TiN.

A thickness of the second layer 113b may range from 50 nm to 500 nm, and, in detail, may range from 200 nm to 300 nm. When a thickness of the second layer 113b is less than 50 nm, the second layer 113b may not significantly relieve tensile stress of the support substrate 111, and when a thickness of the second layer 113b is greater than 500 nm, the second layer 113b may apply excessive compressive stress to the support substrate 111.

However, as compressive stress is applied to the support substrate 111 by the second layer 113b, a level of driving voltage of a package having the semiconductor light emitting device 100 may increase. In order to prevent such a rise in driving voltage, the compressive stress applied to the support substrate 111 by the second layer 113b should be relieved by reapplying tensile stress to the support substrate 111.

The first layer 112a may apply tensile stress to the support substrate 111. In other words, the first layer 112a may relieve compressive stress of the support substrate 111. When a thermal expansion coefficient of the first layer 112a is greater than a thermal expansion coefficient of the support substrate 111, the first layer 112a may apply tensile stress to the support substrate 111.

The first layer 112a may contain at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, and alloys thereof. For example, the first layer 112a may be formed of Al.

A thickness of the first layer 112a may range from 30 nm to 500 nm, and in detail, from 50 nm to 200 nm. When a thickness of the first layer 112a is less than 30 nm, the first layer 112a may not be able to apply significant tensile stress to the support substrate 111, and when a thickness of the first layer 112a is greater than 500 nm, the first layer 112a may apply excessive tensile stress to the support substrate 111.

A first bonding layer 112b may be disposed on the first layer 112a, and a second bonding layer 113a may be disposed below the second layer 113b. The first bonding layer 112b and the second bonding layer 113a may form a bonding layer joining the first layer 112a and the second layer 113b. The bonding layer may include a compound of a first bonding metal and a second bonding metal. The first bonding metal and the second bonding metal may contain at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, Ti, and alloys thereof. For example, the first bonding layer 112b and the second bonding layer 113a may be formed of Ti.

The light emitting structure S may include a first conductivity-type semiconductor layer 116, an active layer 115, and a second conductivity-type semiconductor layer 114.

The first conductivity-type semiconductor layer 116 may be a nitride semiconductor layer satisfying N-type InₓAl_{y}Ga_{1-x-y}N (0≦x<1, 0≦y<1, 0≦x+y<1), and an N-type impurity may be Si. For example, the first conductivity-type semiconductor layer 116 may include N-type GaN.

According to an exemplary embodiment, the first conductivity-type semiconductor layer 116 may include a first conductivity-type semiconductor contact layer 116a and a current diffusion layer 116b. An impurity concentration of the first conductivity-type semiconductor contact layer 116a may range from 2×10¹⁸ cm⁻³ to 9×10¹⁹ cm⁻³. A thickness of the first conductivity-type semiconductor contact layer 116a may range from 1 μm to 5 μm. The current diffusion layer 116b may have a structure in which a plurality of InₓAl_{y}Ga_{(1-x-y)}N (0≦x, y≦1, 0≦x+y≦1) layers having different compositions or different impurity contents are repeatedly stacked. For example, the current diffusion layer 116b may be an N-type superlattice layer in which a plurality of layers including an N-type GaN layer and/or an AlₓIn_{y}Ga_{z}N (0≦x,y,z≦1, x+y+z≠0) layer having a thickness ranging from 1 nm to 500 nm and having different compositions are repeatedly stacked. An impurity concentration of the current diffusion layer 116b may range from 2×10¹⁸ cm⁻³ to 9×10¹⁹ cm⁻³. If necessary, an insulation layer may be additionally introduced to the current diffusion layer 116b.

The second conductivity-type semiconductor layer 114 may be a nitride semiconductor layer satisfying P-type InₓAl_{y}Ga_{1-x-y}N (0≦x<1, 0≦y<1, 0≦x+y<1), and a P-type impurity may be magnesium (Mg). For example, the second conductivity-type semiconductor layer 114 may have a single-layer structure but, as illustrated in the present exemplary embodiment, have a multilayer structure comprising layers having different compositions. As illustrated in FIG. 1, the second conductivity-type semiconductor layer 114 may include an electron-blocking layer (EBL) 114a, a low-concentration P-type GaN layer 114b, and a high-concentration P-type GaN layer 114c provided as a contact layer. For example, the electron-blocking layer 114a may have a structure in which a plurality of InₓAl_{y}Ga_{(1-x-y)}N (0≦x≦1, 0≦y≦1, 0≦x+y≦1) layers having a thickness between 5 nm to 100 nm and having different compositions are stacked, or a single-layer structure formed of Al_{y}Ga_{(1-y)}N (0<y≦1). An energy band gap of the electron-blocking layer 114a may decrease as a distance of the electron-blocking layer 114a from the active layer 115 increases. For example, an Al composition of the electron-blocking layer 114a may decrease as a distance of the electron-blocking layer 114a from the active layer 115 increases.

The active layer 115 may have a multiple quantum well (MQW) structure in which a quantum well layer and a quantum barrier layer are alternately stacked. For example, the quantum well layer and the quantum barrier layer may be InₓAl_{y}Ga_{1-x-y}N (0≦x≦1, 0≦y≦1, 0≦x+y≦1) layers having different compositions from each other. For example, the quantum well layer may be InₓGa₁₋ₓN (0<x≦1), and the quantum barrier layer may be GaN or AlGaN. Respective thicknesses of the quantum well layer and the quantum barrier layer may range from 1 nm to 50 nm. A structure of the active layer 115 may not be limited to the multi quantum well structure, and may be a single quantum well structure.

The semiconductor light emitting device 100 may include an ohmic contact layer 118 and an electrode layer 119 sequentially stacked on the first conductivity-type semiconductor layer 114.

The electrode layer 119 may include a material such as Ag, Ni, Al, Cr, Rh, Pd, Ir, Ru, Mg, Zn, Pt, Au, and the like, but is not limited thereto, and may have a single-layer structure or a multilayer structure. The electrode layer 119 may further include a pad electrode layer thereon. The pad electrode layer may be a layer containing at least one material of Au, Ni, Sn, and the like.

The ohmic contact layer 118 may be implemented in a variety of ways depending on a chip structure. For example, in a case in which the semiconductor light emitting device 100 has a flip-chip structure, the ohmic contact layer 118 may include a metal such as Ag, Au, Al, and the like, and a transparent conductive oxide such as indium tin oxide (ITO), zinc indium oxide (ZIO), gallium indium oxide (GIO), and the like. In a case in which the semiconductor light emitting device 100 has a structure different from the flip-chip structure, the ohmic contact layer 118 may be formed of a light-transmitting electrode. The light-transmitting electrode may be any one of a transparent conductive oxide layer or a nitride layer. For example, the light-transmitting electrode may be one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂, and zinc magnesium oxide, Zn₍₁₋ₓ₎MgₓO (0≦x≦1). If necessary, the ohmic contact layer 118 may include graphene. The electrode layer 119 may include at least one of Al, Au, Cr, Ni, Ti, and Sn.

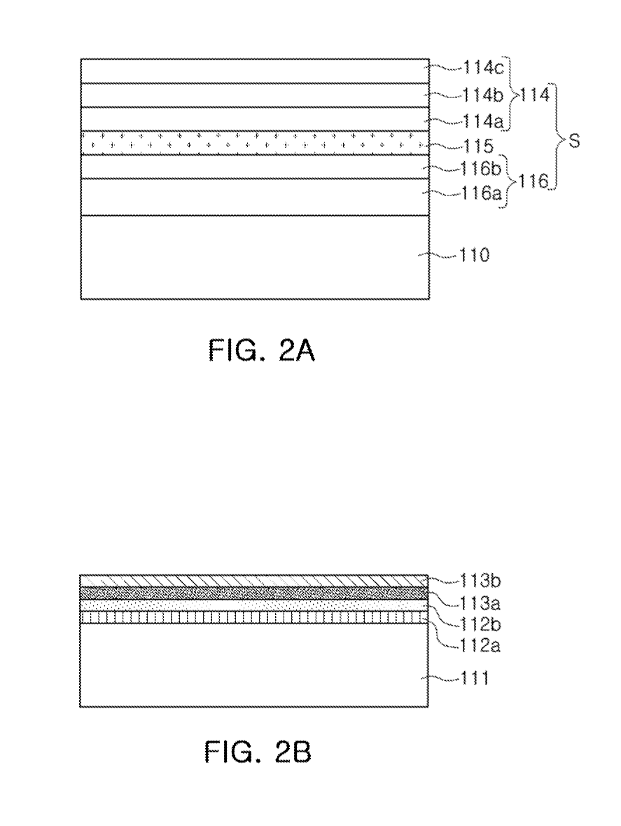

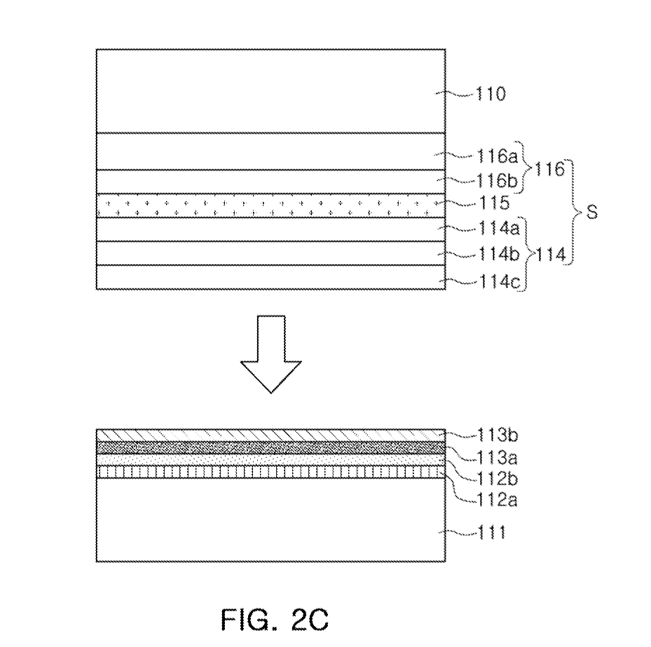

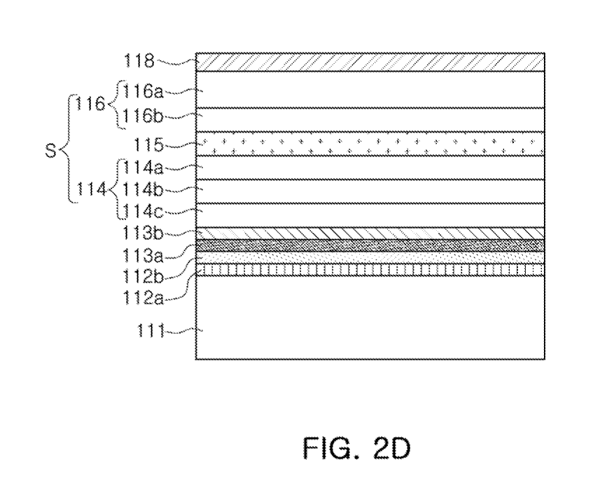

FIGS. 2A to 2E are schematic cross-sectional views illustrating a method of manufacturing a semiconductor light emitting device according to an exemplary embodiment. Descriptions of the same elements as those of FIG. 1 will be omitted.

Referring to FIG. 2A, a light emitting structure S may be grown on a growth substrate 110. The growth substrate 110 may be provided as a silicon substrate, and in detail, may have a diameter ranging from 6 to 18 inches and a thickness ranging from 500 μm to 1500 μm. A first conductivity-type semiconductor layer 116, an active layer 115, and a second conductivity-type semiconductor layer 114 may be sequentially grown on the growth substrate 110. The second conductivity-type semiconductor layer 114 may have a structure in which an electron-blocking layer 114a, a low-concentration P-type GaN layer 114b, and a high-concentration P-type GaN layer 114c are sequentially stacked. The first conductivity-type semiconductor layer 116 may have a structure in which a first conductivity-type semiconductor contact layer 116a and a current diffusion layer 116b are sequentially stacked. In a case in which the growth substrate 110 is a silicon substrate, the light emitting structure S may have tensile stress.

Referring to FIG. 2B, a first layer 112a, a first bonding layer 112b, a second bonding layer 113a, and a second layer 113b may be sequentially stacked on a support substrate 111. The first layer 112a and the first bonding layer 112b may be deposited by an e-beam evaporator, and the second layer 113b and the second bonding layer 113a may be formed by a sputtering process.

Referring to FIG. 2C, the light emitting structure S grown on the growth substrate 110 in FIG. 2A may be bonded to the support substrate 111 on which the first layer 112a, the first bonding layer 112b, the second bonding layer 113a, and the second layer 113b are sequentially formed. The first bonding layer 112b and the second bonding layer 113a may be bonded to each other to form a single bonding layer.

In a case in which the light emitting structure S is directly bonded to the support substrate 111 without the first layer 112a, the first bonding layer 112b, the second bonding layer 113a, and the second layer 113b, tensile stress may occur in the support substrate 111. In a case in which tensile stress occurs and remains, handling thereof in a manufacturing process of the semiconductor light emitting device 100 may be difficult.

Referring to FIG. 2D, an ohmic contact layer 118 may be formed on the first conductivity-type semiconductor layer 116 after the growth substrate 110 is removed from the light emitting structure S. Removal of the growth substrate 110 may be performed through a laser lift-off process or a mechanical method such as grinding and the like.

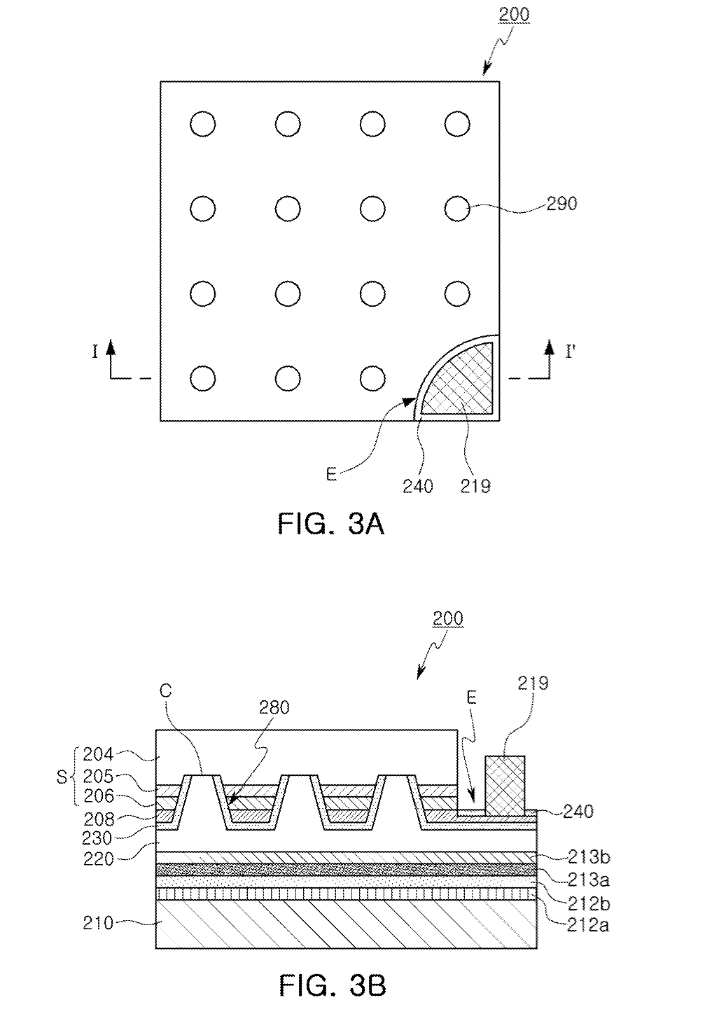

FIGS. 3A to 3B are plan-view and cross-sectional view respectively, illustrating a semiconductor light emitting device according to an exemplary embodiment. FIG. 3B is a cross-sectional view taken along line I-I′ of FIG. 3A. Descriptions of the same elements as those of FIG. 1 will be omitted.

Referring to FIG. 3A and FIG. 3B, a semiconductor light emitting device 200 may be provided for lighting apparatuses and have a large area for great power output. The semiconductor light emitting device 200 may have a structure to improve current spreading efficiency and heat radiation efficiency thereof.

The semiconductor light emitting device 200 may include a light-emitting stack S, a first electrode 220, an insulation layer 230, a second electrode 208, and a support substrate 210. A first layer 212a, a first bonding layer 212b, a second bonding layer 213a, and a second layer 213b may be sequentially disposed between the first electrode 220 and the support substrate 210. The first bonding layer 212b and the second bonding layer 213a may be bonded to each other to form a single bonding layer.

The first layer 212a may apply tensile stress to the support substrate 210. In other words, the first layer 212a may relieve compressive stress of the support substrate 210. When a thermal expansion coefficient of the first layer 212a is greater than a thermal expansion coefficient of the support substrate 210, the first layer 212a may apply tensile stress to the support substrate 210.

The second layer 213b may apply compressive stress to the support substrate 210. In other words, the second layer 213b may relieve tensile stress of the support substrate 210. When a thermal expansion coefficient of the second layer 213b is smaller than a thermal expansion coefficient of the first layer 212a, the second layer 213b may relieve tensile stress applied to the support substrate 210 by the first layer 212a.

The first bonding layer 213a and the second bonding layer 213b may bond the first layer 212a and the second layer 213b.

The light-emitting stack S may include a first conductivity-type semiconductor layer 204, an active layer 205, and a second conductivity-type semiconductor layer 206 sequentially stacked.

The first electrode 220 may include one or more conductive vias 280 electrically insulated from the second conductivity-type semiconductor layer 206 and the active layer 205 and extended to at least a portion of the first conductivity-type semiconductor layer 204, so as to be electrically connected to the first conductivity-type semiconductor layer 204. The conductive via 280 may penetrate through the second electrode 208, the second conductivity-type semiconductor layer 206, and the active layer 205 from the first electrode 220, to be extended into the first conductivity-type semiconductor layer 204. The conductive via 280 may be formed through an etching process such as inductively coupled plasma reactive-ion etching (ICP RIE) and the like.

An insulation layer 230 may be provided on the first electrode 220 such that the first electrode 220 may be electrically insulated from regions other than the conductive substrate 210 and the first conductivity-type semiconductor layer 204. As illustrated in FIG. 3B, the insulation layer 230 may be formed on a side surface of the conductive via 280 as well as between the second electrode 208 and the first electrode 220. Thus, the first electrode 220 may be insulated from the second electrode 208, the second conductivity-type semiconductor layer 206, and the active layer 205 exposed to the side surface of the conductive via 280. The insulation layer 230 may be formed by the deposition of an insulation material such as SiO₂, SiOₓN_{y}, and SiₓN_{y}.

A contact region C of the first conductivity-type semiconductor layer 204 may be exposed by the conductive via 280, and a portion of the first electrode 220 may be formed to come into contact with the contact region C through the conductive via 280. Thus, the first electrode 220 may be connected to the first conductivity-type semiconductor layer 204.

The number, shape, pitch, contact diameter (or contact area) with regard to the first and second conductivity-type semiconductor layers 204 and 206 of the conductive via 280 may be appropriately adjusted so that contact resistance of the conductive via 280 may decrease (see FIG. 3A), and the conductive via 280 may be arrayed in rows and columns in a variety of forms so as to improve the flow of current. The number and contact area of the conductive via 280 may be adjusted so that an area of the contact region C can be between approximately 0.1% and 20% of a planar area of the light emitting stack S. For example, the area of the contact region C may be 0.5% to 15% of the planar area of the light emitting stack S, and in detail, 1% to 10% thereof. In a case in which the area of the contact region C is less than 0.1% of the planar area of the light emitting stack S, current spreading may not be uniform, and thus, light emission characteristics may be degraded. In a case in which the area of the contact region C is greater than 20% of the planar area of the light emitting stack S, the light emitting area may be reduced, and thus, the light emission characteristics may be degraded and a level of luminance may be decreased.

A radius of the conductive via 280 in a region coming into contact with the first conductivity-type semiconductor layer 204 may range from 1 μm to 50 μm, and the number of the conductive vias 280 may be 1 to 48,000 per region of the light-emitting stack S, depending on an area of the light emitting stack S. The number of the conductive vias 280 may vary depending on the area of the light emitting stack S, but may be 2 to 45,000, 5 to 40,000, or 10 to 35,000. The conductive via 280 may have a matrix structure in which a distance between each conductive via 280 may range from 10 μm to 1,000 μm, from 50 μm to 700 μm, from 100 μm to 500 μm, or from 150 μm to 400 μm.

In a case in which the distance between each conductive via 280 is less than 10 μm, the number of the conductive vias 280 may increase, while the light emitting area may relatively decrease, and thus, light emitting efficiency may be reduced. In a case in which the distance between each conductive via 280 is greater than 1000 μm, current may not flow appropriately, and thus, light emitting efficiency may be reduced. A depth of the conductive via 280 may be determined by thicknesses of the second conductivity-type semiconductor layer 206 and the active layer 205, and may be between, for example, 0.1 μm and 5.0 μm.

As illustrated in FIG. 3B, the second electrode 208 may be extended outside of the light-emitting stack S to provide an electrode-forming region E. The electrode-forming region E may have an electrode pad 219 to connect externally-supplied power to the second electrode 208. The electrode-forming region E is illustrated as being singular, but if necessary, a plurality of electrode-forming regions may be formed. As illustrated in FIG. 3A, in order to significantly increase the light emitting area, the electrode-forming region E may be formed in a corner of the nitride semiconductor light emitting device 200.

According to an exemplary embodiment, an insulation layer for an etch stop 240 may be disposed around the electrode pad 219. The insulation layer for an etch stop 240 may be formed in the electrode-forming region E after the light emitting stack S is formed and before the second electrode 208 is formed. The insulation layer for an etch stop 240 may serve as an etch stop layer during an etching process for the electrode-forming region E.

The second electrode 208 may be formed of a material having ohmic contact with the second conductivity-type semiconductor layer 206 and having a relatively high reflectivity. As the material forming the second electrode 208, a reflective electrode material described above may be used.

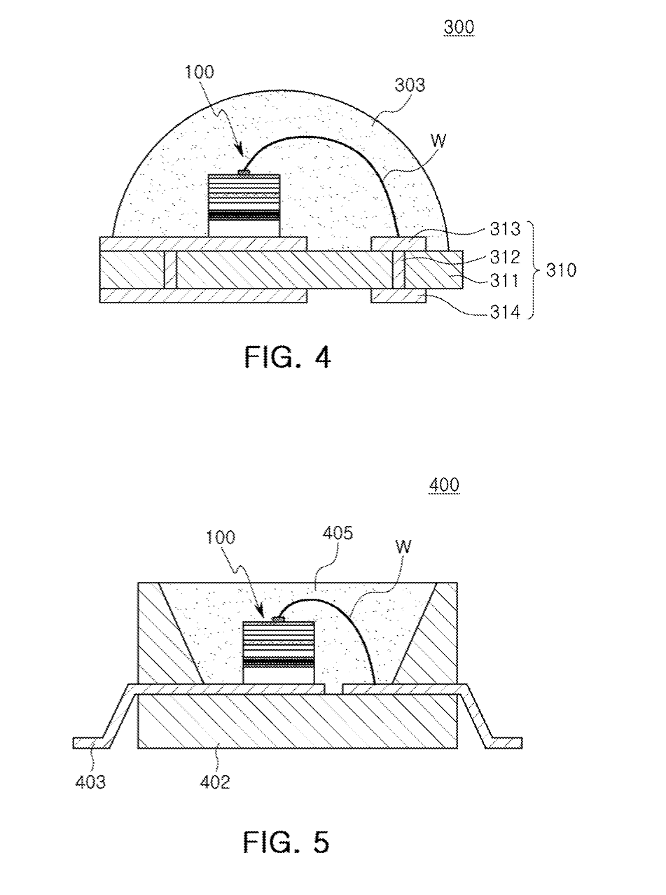

FIG. 4 is a cross-sectional view illustrating a semiconductor light emitting device package employing a semiconductor light emitting device according to an exemplary embodiment.

Referring to FIG. 4, a semiconductor light emitting device package 300 may include the semiconductor light emitting device 100 of FIG. 1, a mounting substrate 310, and an encapsulating module 303. The semiconductor light emitting device 100 may be mounted on the mounting substrate 310 and electrically connected to the mounting substrate 310 by a wire W. The mounting substrate 310 may include a main body 311, an upper electrode 313, a lower electrode 314, and a penetrating electrode 312 connecting the upper electrode 313 and the lower electrode 314 to each other. The main body 311 of the mounting substrate 310 may be formed of a resin, a ceramic, or a metal, and the upper electrode 313 or the lower electrode 314 may be formed of a metal such as Au, Cu, Ag, and Al. For example, the mounting substrate 310 may be provided as a silicon substrate. The mounting substrate 310 may be provided as a substrate of a printed circuit board (PCB), a metal core printed circuit board (MCPCB), a metal printed circuit board (MPCB), a flexible printed circuit board (FPCB), and the like, and a structure thereof may be formed in a variety of manners.

The encapsulating module 303 may be formed to have a dome-shaped lens structure having a convex upper surface, but depending on exemplary embodiments, a beam spread angle of light emitted through the upper surface of the encapsulating module 303 may be adjusted by forming the structure of the lens to be convex or concave.

FIG. 5 is a cross-sectional view illustrating a semiconductor light emitting device package employing a semiconductor light emitting device according to an exemplary embodiment.

Referring to FIG. 5, a semiconductor light emitting device package 400 may include the semiconductor light emitting device 100 of FIG. 1, a package main body 402, and a pair of lead frames 403.

The semiconductor light emitting device 100 may be mounted on the lead frames 403 so that each electrode thereof can be electrically connected to the lead frames 403 by a wire W. If necessary, the semiconductor light emitting device 100 may be mounted not on the lead frames 403, but on other parts such as the package main body 402. The package main body 402 may include a cup-shaped recess so that light reflection efficiency can be increased, and in the recess, an encapsulating module 405 formed of a light transmitting material may be formed to encapsulate the semiconductor light emitting device 100, the wire W, and the like.

If necessary, a wavelength conversion material such as a phosphor and/or a quantum dot may be contained in the encapsulating module 405. The wavelength conversion material will be described below.

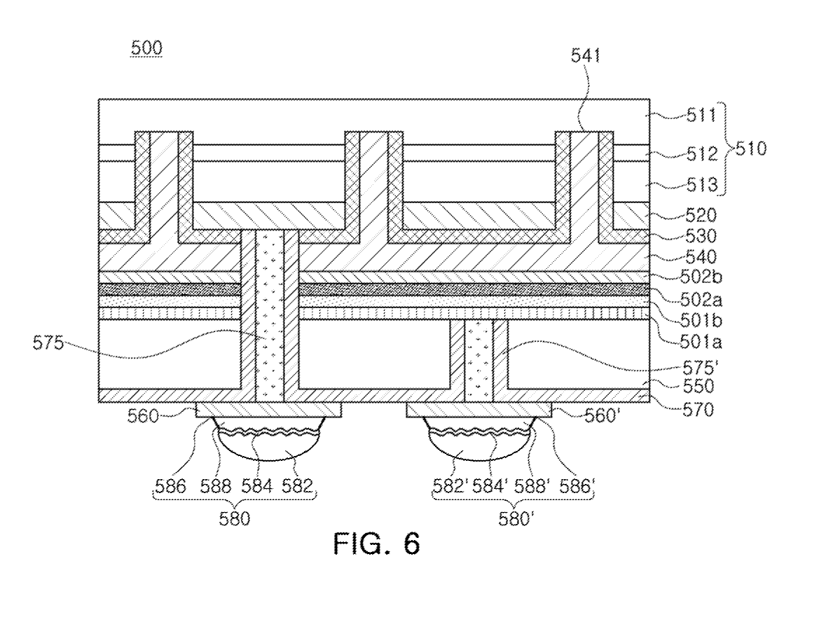

FIG. 6 is a cross-sectional view illustrating a semiconductor light emitting device according to an exemplary embodiment.

Referring to FIG. 6, a semiconductor light emitting device 500 according to an exemplary embodiment may include a first conductivity-type semiconductor layer 511, an active layer 512, a second conductivity-type semiconductor layer 513, a second electrode layer 520, a first electrode layer 540, and a support substrate 550, sequentially stacked. A first layer 501a, a first bonding layer 501b, a second bonding layer 502a, and a second layer 502b may be sequentially disposed between the first electrode layer 540 and the support substrate 550. The first conductivity-type semiconductor layer 511, the active layer 512, and the second conductivity-type semiconductor layer 513 may form a light emitting stack 510.

The first layer 501a may apply tensile stress to the support substrate 550. In other words, the first layer 501a may relieve compressive stress of the support substrate 550. When a thermal expansion coefficient of the first layer 501a is greater than a thermal expansion coefficient of the support substrate 550, the first layer 501a may be able to apply tensile stress to the support substrate 550.

The second layer 502b may apply compressive stress to the support substrate 550. In other words, the second layer 502b may relieve tensile stress of the support substrate 550. When a thermal expansion coefficient of the second layer 502b is smaller than a thermal expansion coefficient of the first layer 501a, the second layer 113b may relieve tensile stress applied to the support substrate 550 by the first layer 501a.

The first bonding layer 501b and the second bonding layer 502a may bond the first layer 501a and the second layer 502b.

The first electrode layer 540 may include one or more contact holes 541 electrically connected to the first conductivity-type semiconductor layer 511 and extended to at least a portion of the first conductivity-type semiconductor layer 511 from a surface of the first electrode 540. The first electrode layer 540 may be electrically insulated from the second electrode layer 520, the second conductivity-type semiconductor layer 513, and the active layer 512 by a first insulation layer 530.

At least a portion of the first insulation layer 530 may have a multilayer structure and serve to reflect light from the active layer 512. The first insulation layer 530 may reflect light emitted downwardly from the active layer 512 to redirect the light upwardly. The multilayer structure may be form by alternately stacking two insulation layers having different refractive indices. The multilayer-structure insulation layer may be provided as a distributed Bragg reflector by appropriately adjusting refractive indices and thicknesses of insulation layers forming the multilayer-structure insulation layer.

When a wavelength of light generated in the active layer 512 is λ, and a refractive index of each insulation layer is n, a thickness of each layer forming the multilayer-structure insulation layer may be λ/4n. In detail, the thickness of each insulation layer may range from 20 Å to 2000 Å. Here, the respective refractive indices and thicknesses of the insulation layers forming the multilayer-structure insulation layer may be designed such that these insulation layers have relatively high reflectivity (70% or above) against a wavelength of the light generated in the active layer 512. For example, the respective thicknesses of these insulation layers may be equal to or different from one another.

Each of the refractive indices of the insulation layers forming the multilayer-structure insulation layer may be determined to be between 1.1 and 2.5.

According to an exemplary embodiment, the insulation layers forming the multilayer-structure insulation layer may be alternately stacked 2 to 40 times to form a reflective structure.

The multilayer-structure insulation layer may be formed of at least one selected from a group consisting of SiO₂, SiN, SiOₓN_{y}, TiO₂, Si₃N₄, Al₂O₃, TiN, AlN, ZrO₂, TiAlN, and TiSiN.

A second conductive via 575 penetrating the first electrode layer 540 and the support substrate 550 to electrically connect the second electrode layer 520 and a second electrode pad 560 formed on an undersurface of a second insulation layer 570 may be formed. In addition, a first conductive via 575′ penetrating the support substrate 550 to electrically connect the first electrode layer 540 and a first electrode pad 560′ formed on an undersurface of the second insulation layer 570 may be formed. The second insulation layer 570 covering entire side surfaces of the second conductive via 575 and the first conductive via 575′ and disposed along an undersurface of the support substrate 550 may be formed in such a manner that the second conductive via 575 can be electrically insulated from the first electrode layer 540 and the support substrate 550, and the first conductive via 575′ can be electrically insulated from the support substrate 550.

Interconnected bumps may be disposed under the first electrode pad 560′ and the second electrode pad 560. The interconnected bumps may include a first bump 580′ and a second bump 580, and be respectively connected to the first conductivity-type semiconductor layer 511 and the second conductivity-type semiconductor layer 513 by the first conductive via 575′ and the second conductive via 575. The first bump 580′ and the second bump 580 may be disposed in the semiconductor light emitting device 500 in a single direction.

The first bump 580′ may include an under bump metallurgy (UBM) layer 588′, an intermetallic compound (IMC) 584′, and a solder bump 582′ sequentially disposed thereon. The second bump 580 may include an under bump metallurgy (UBM) layer 588, an intermetallic compound (IMC) 584, and a solder bump 582 sequentially disposed thereon. In addition, the UBM layer 588′ may include a barrier layer 586′ formed on a side surface thereof. The UBM layer 588 may include a barrier layer 586 formed on a side surface thereof. The number of each of the first bump 580′ and the second bump 580 may be one or more.

Each of the UBM layers 588′ and 588 may improve the bonding power of the interfaces between the first electrode pad 560′ and the solder bump 582′, and between the second electrode pad 560 and the solder bump 582, as well as provide an electrical passage. In addition, the UBM layers 588′ and 588 may respectively prevent solder from being diffused into the first electrode pad 560′ and the second electrode pad 560 during a reflow process. In detail, the UBM layers 588′ and 588 may respectively prevent a solder ingredient from permeating into the first electrode pad 560′ and the second electrode pad 560.

The UBM layers 588′ and 588 may be formed of a metal so as to be electrically connected to the first electrode pad 560′ and the second electrode pad 560, respectively.

For example, the UBM layers 588′ and 588 may have a multilayer-film structure in which a titanium (Ti) layer, in contact with the first and second electrode pads 560′ and 560, and a nickel (Ni) layer disposed on the Ti layer are stacked. In addition, although not illustrated, the UBM layers 588′ and 588 may have a multilayer structure including a copper layer disposed on the Ti layer, instead of the Ni layer.

In the present exemplary embodiment, the UBM layers 588′ and 588 have been illustrated to have a Ti—Ni multilayer structure, but are not limited thereto. For example, the UBM layers 588′ and 588 may have a multilayer structure including a chrome (Cr) layer in contact with the first and second electrode pads 560′ and 560, and a nickel layer disposed on the Cr layer, or a multilayer structure including a Cr layer and a copper (Cu) layer disposed on the Cr layer.

In addition, in the present exemplary embodiment, the UBM layers 588′ and 588 have been illustrated to have a multilayer structure, but are not limited thereto. For example, the UBM layers 588′ and 588 may have a single-layer structure including a nickel (Ni) layer or a copper (Cu) layer.

The UBM layers 588′ and 588 may be formed using a process such as sputtering, e-beam depositing, and plating.

Each of the IMCs 584′ and 584 may be formed on an undersurface of the UBM layers 588′ and 588, respectively. The IMCs 584′ and 584 may be formed during a reflow process in which the solder bumps 582 and 582′ are formed. The IMCs 584′ and 584 may be formed as tin (Sn) in the solder reacts to a metal in the UBM layers 588′ and 588 such as nickel (Ni), thereby forming a binary alloy of Sn—Ni.

The solder bumps 582′ and 582 may be respectively bonded to the UBM layers 588′ and 588, with the IMCs 584′ and 584 serving as a medium. In detail, the solder bumps 582′ and 582 may be strongly bonded to lower surfaces of the UBM layers 588′ and 588, respectively, by the IMCs 584′ and 584 serving as adhesives.

The solder bumps 582′ and 582 may be formed by reflowing the solder under the UBM layers 588′ and 588. For the solder, for example, SAC305 (Sn_{96.5}Ag_{3.0}Cu_{0.5}) may be used.

The barrier layers 586 and 586′ may be formed to cover side surfaces of the UBM layers 588 and 588′. The barrier layer 586′ and 586 may have a structure gently tilted towards the first and second electrode pads 560′ and 560 from the IMCs 584′ and 584, respectively. In addition, although not illustrated, the barrier layers 586′ and 586 may be perpendicularly extended to lower surfaces of the first and second electrode pads 560′ and 560.

The IMCs 584 and 584′ and the solder bumps 582 and 582′ may be prevented from being diffused to the side surfaces of the UBM layers 588 and 588′ by significantly reducing wettability of the barrier layers 586 and 586′ against the solder bumps 582 and 582′. This may be implemented by forming the barrier layers 586 and 586′ to have low wettability against the IMCs 584 and 584′ and the solder bumps 582 and 582′. Thus, the IMCs 584 and 584′ or the solder bumps 582 and 582′ may not be formed on the barrier layers 586 and 586′.

The barrier layers 586 and 586′ may be an oxide film containing at least one element of the UBM layers 588 and 588′. For example, the barrier layers 586 and 586′ may be an oxide film containing at least one element of nickel (Ni) and copper (Cu).

The barrier layers 586 and 586′ may be formed by oxidizing the side surfaces of the UBM layers 588 and 588′. For example, the barrier layers 586 and 586′ may be formed by oxidizing the side surfaces of the UBM layers 588 and 588′ during a thermal oxidation process or a plasma oxidation process.

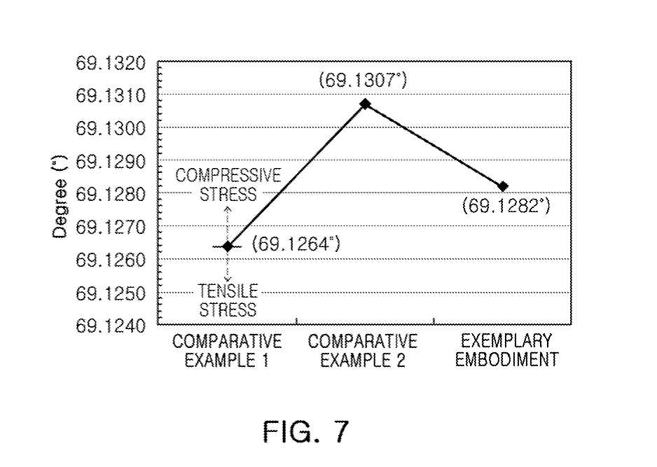

FIG. 7 is a diagram comparing X-ray diffraction (XRD) results of the present exemplary embodiment, comparative example 1, and comparative example 2, according to an exemplary embodiment.

The present exemplary embodiment is the semiconductor light emitting device illustrated in FIG. 1, and comparative example 1 is a bare silicon substrate. Comparative example 2 is a semiconductor light emitting device 100 of FIG. 1 employing a light emitting structure S grown on the silicon substrate from which the second layer 113b and the second bonding layer 113a thereof are removed. Comparative example 3 is a semiconductor light emitting device 100 of FIG. 1 employing a light emitting structure S grown on a sapphire substrate from which the first layer 112a, the first bonding layer 112b, the second layer 113b, and the second bonding layer 113a thereof are removed. Here, the first layer 113b is formed of TiN, the second layer 112a is formed of Al, the first and second bonding layers 113a and 112b are formed of Ti, and the support substrate 111 may be provided as a silicon substrate.

Referring to FIG. 7, an XRD peak measured on a silicon (004) surface of comparative example 1 is 69.1264°, an XRD peak measured on a silicon (004) surface of comparative example 2 is 69.1307°, and an XRD peak measured on a silicon (004) surface of the present exemplary embodiment is 69.1282°. When a TiN/Ti layer is interposed between a silicon support substrate and a light emitting structure to bond the silicon support substrate and the light emitting structure (comparative example 2), compressive stress of the silicon support substrate may increase as compared to compressive stress of the bare silicon substrate (comparative example 1), and when a TiN/Ti-Ti/Al layer is interposed between the silicon support substrate and the light emitting structure to bond the silicon support substrate and the light emitting structure (the present exemplary embodiment), compressive stress of the silicon supporting substrate may be relieved.

Table 1 illustrates comparison of operating voltages of the semiconductor light emitting devices of the present exemplary embodiment, comparative example 2, and comparative example 3 when the operating current of 1 A is applied thereto after the semiconductor light emitting devices of the present exemplary embodiment, comparative example 2, and comparative example 3 are die-attached, wire-bonded, packaged, and then treated by heating at 190° C. for 30 minutes.

TABLE 1

| | Exemplary | Comparative | Comparative |
|---|---|---|---|
| | Embodiment | Example 2 | Example 3 |
| Operating | 3.66 V | 4.22 V | 3.79 V |
| Voltage | | | |

Referring to Table 1 above, the operating voltage of the present exemplary embodiment is lower than the operating voltage of comparative example 2, and lower even than the operating voltage of comparative example 3. Thus, when a semiconductor light emitting device has the same configuration as a configuration of the present exemplary embodiment, and a support substrate thereof is a silicon support substrate, a problem occurring during a manufacturing process due to bending of a support substrate occurring due to stress applied thereto may be reduced, and the operating voltage thereof may also be decreased. When the operating voltage is decreased, light emitting efficiency of the semiconductor light emitting device may increase.

Since light emitting efficiency of a semiconductor light emitting device may decrease when operating voltage thereof increases, light emitting efficiency of the semiconductor light emitting device according to the present exemplary embodiment may increase by relieving stress applied to a light emitting structure thereof.

Referring to Table 1 and FIG. 7, when compressive stress is relieved in the present exemplary embodiment comparing compressive stress of comparative example 2, the operating voltage may be decreased, which indicates that the reason the operating voltage of a semiconductor light emitting device increases when a TiN/Ti layer is interposed between a silicon support substrate and a light emitting structure grown on a silicon growth substrate may be compressive stress applied to the silicon support substrate.

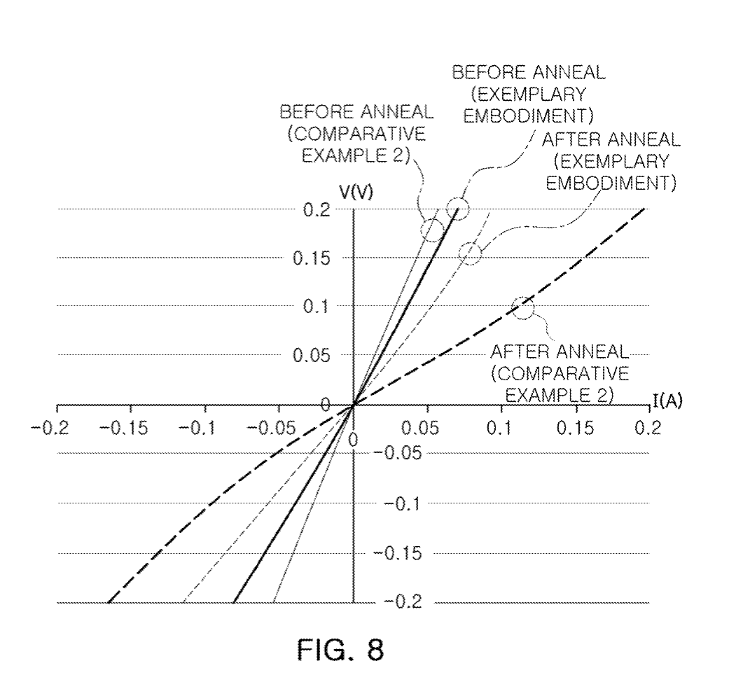

FIG. 8 is a graph illustrating current-voltage (I-V) changes of the present exemplary embodiment and comparative example 2 before and after the present exemplary embodiment and comparative example 2 are annealed at 190° C., according to an exemplary embodiment.

Referring to FIG. 8, the I-V curve of comparative example 2 shows ohmic characteristics before annealing, and shows Schottky characteristics after annealing. However, the I-V curve of the present exemplary embodiment shows relatively little change before and after annealing. This shows that the height of a Schottky barrier of the present exemplary embodiment may become lower than the height of a Schottky barrier of comparative example 2 as compressive stress of the silicon support substrate of the present exemplary embodiment is relieved by adding a Ti/Al layer below a TiN/Ti layer.

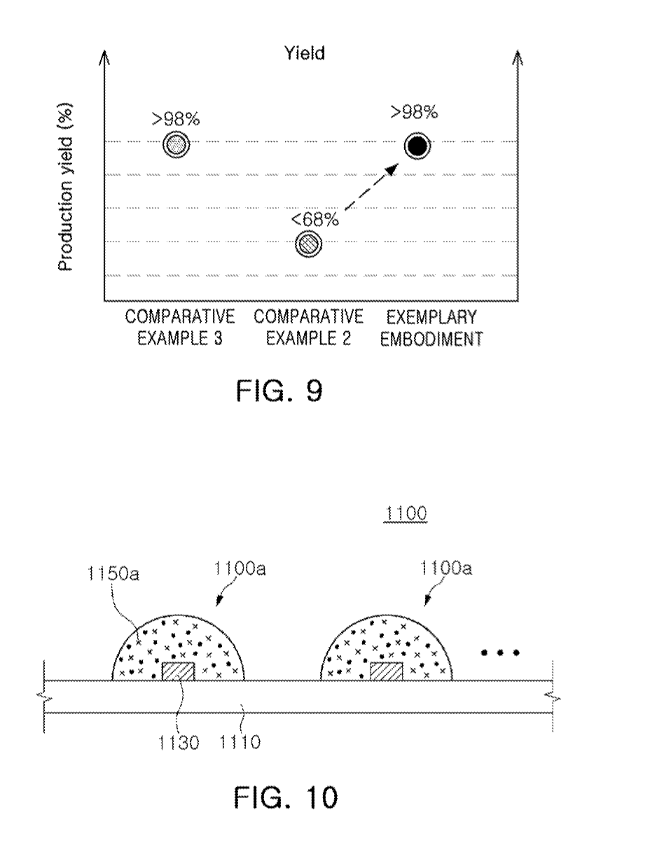

FIG. 9 is a graph comparing production yield rates of the present exemplary embodiment, comparative example 2, and comparative example 3, according to an exemplary embodiment. Here, the production yield rate refers to a percentage of semiconductor light emitting device packages having an average operating voltage of 4.2V or lower among all semiconductor light emitting device packages manufactured.

Referring to FIG. 9, a production yield rate of comparative example 2 is 68% or lower, but a production yield rate of the present exemplary embodiment is 98% or higher, almost the same as a production yield rate of comparative example 3 having a light emitting structure grown on a sapphire substrate.

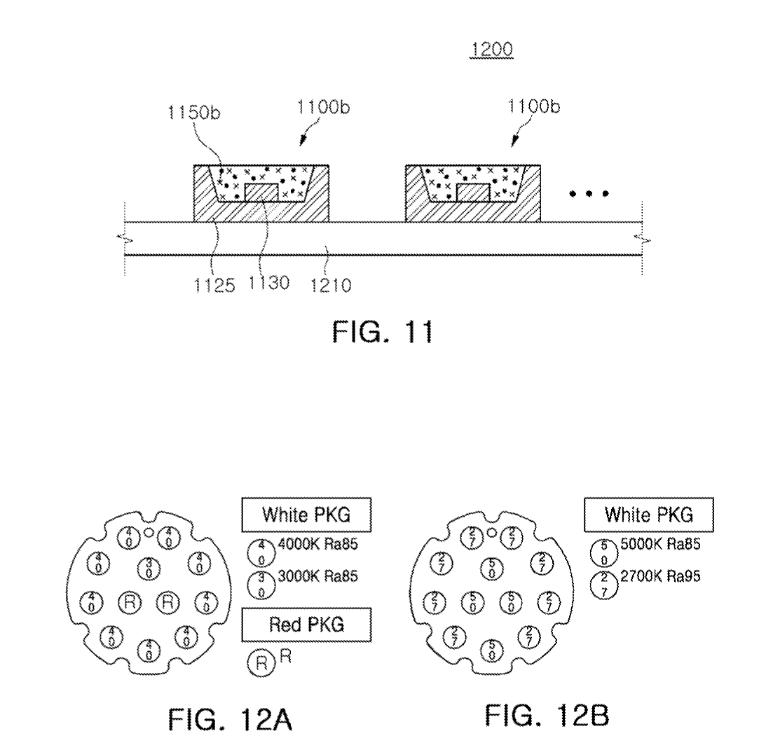

FIGS. 10 and 11 are cross-sectional views schematically illustrating white light source modules employing a semiconductor light emitting device of the above exemplary embodiment, according to exemplary embodiments.

Referring to FIG. 10, a light source module for an LCD backlight 1100 may include a circuit board 1110 and a plurality of white light emitting devices 1100a arranged and mounted on the circuit board 1100. A conductive pattern connected to the white light emitting devices 1100a may be formed on an upper surface of the circuit board 1110.

Each of the white light emitting devices 1100a may have a structure in which a light emitting device 1130 emitting blue light may be directly mounted on the circuit board 1110 in a chip on board (COB) manner. Each of the white light emitting devices 1100a may not include a separate reflective wall, and a wavelength converter 1150a having a hemispherical shape may be included therein while having a function of a lens to allow light having a relatively wide angle of beam spread to be emitted therefrom. Such a wide angle of beam spread may contribute to decreasing thickness or width of LCD displays.

Referring to FIG. 11, a light source module for an LCD backlight 1200 may include a circuit board 1210 and a plurality of white light emitting devices 1100b arranged and mounted on the circuit board 1210. Each of the white light emitting devices 1100b may include a light emitting device 1130 emitting blue light and mounted in a reflective cup of a package main body 1125, and a wavelength converter 1150b encapsulating the light emitting device 1130.

If necessary, the wavelength converters 1150a and 1150b may contain a wavelength conversion material such as a phosphor and/or a quantum dot. A detailed description of the wavelength conversion material will be provided below.

FIGS. 12A and 12B are views schematically illustrating a white light source module which may be employed by a lighting device, according to exemplary embodiments.

Referring to FIGS. 12A and 12B, each of the light source modules may include a plurality of light emitting device packages mounted on a circuit substrate thereof. The plurality of light emitting device packages employed by a single light source module may be an identical kind of light emitting device package generating a same wavelength of light, but as illustrated in FIGS. 12A and 12B, may comprise different kinds of light emitting device package generating different wavelengths of light.

Referring to FIG. 12A, a white light source module may include white light emitting device packages having color temperatures of 4000K and 3000K, and red light emitting device packages. The color temperature of the white light source module may be adjusted to be between 3000K and 4000K, and the white light source module may provide white light having a color rendering index Ra of 85 to 100.

Referring to FIG. 12B, a white light source module may include only white light emitting device packages having different color temperatures. For example, the color temperatures of the white light source module may be adjusted to be between 2700K and 5000K by configuring the white light source module of white light emitting device packages having a color temperature of 2700K and white light emitting device packages having a color temperature of 5000K, and the white light source module may provide white light having a color rendering index Ra of 85 to 99. Here, the numbers of the white light emitting device packages having a color temperature of 2700K and the white light emitting device packages having a color temperature of 5000K may be adjusted depending on the color temperature setup values thereof. For example, in the case of a lighting device having a color temperature setup value of about 4000K, the number of light emitting device packages having a color temperature of 4000K may be greater than the number of light emitting device packages having a color temperature of 3000K or red light emitting device packages.

As described above, different kinds of light emitting device packages may include a white light emitting device made by adding a yellow, green, red, or orange phosphor to a blue light emitting device, and at least one of purple, blue, green red, and infrared light emitting devices, such that the color temperature and color rendering index (CRI) of the white light may be adjusted.

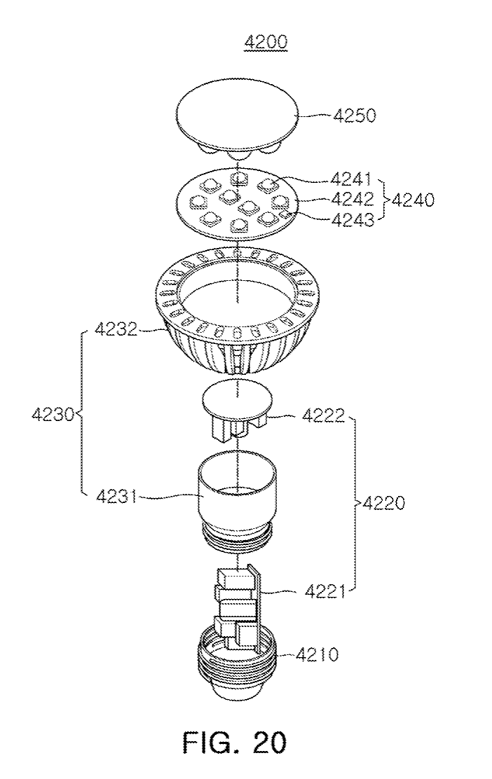

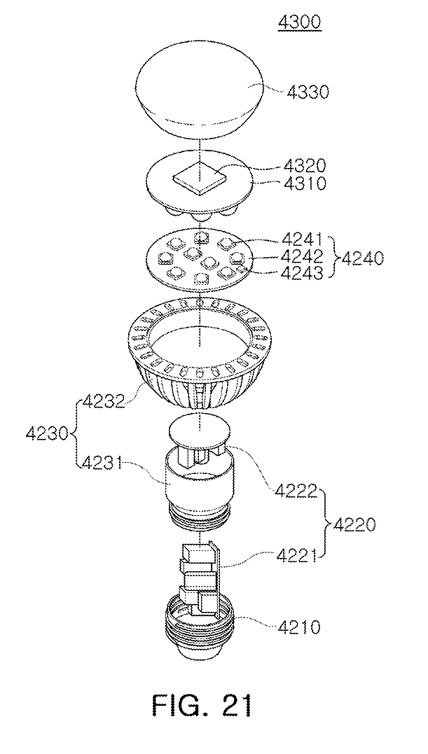

The white light source module described above may be used as a light source module 4240 of a bulb-type lighting device (4200 of FIG. 20 or 4300 of FIG. 21).

In a case in which a white light source module employs an identical kind of light emitting device packages, the color of light may be determined according to the wavelength of a light emitting diode (LED) chip, a light emitting device, and a type and a mixing ratio of phosphors. In a case in which the LED chip emits white light, the color temperature and color rendering index thereof may be adjusted.

For example, in a case in which the LED chip emits blue light, a light emitting device package including at least one of yellow, green, and red phosphors may be adjusted to emit white light having a variety of color temperatures depending on a mixing ratio of the phosphors. On the other hand, in a case in which a green or red phosphor is applied to a blue LED chip, a light emitting device package thereof may be adjusted to emit green light or red light. As described above, the color temperature and the color rendering index of white light may be adjusted by mixing a white light emitting device package with a green or red light emitting device package. In addition, the white light source module may be configured to include at least one light emitting device emitting purple, blue, green, red, or infrared light.

In this case, the color rendering index of the lighting device may be adjusted from a level of light from a sodium lamp to a level of sunlight, and the lighting device may generate white light having a wide range of color temperature between 1500K and 20000K. If necessary, the lighting device may adjust the color of light by generating purple, blue, green, red, or orange visible light, or infrared light for the desired mood. In addition, light having a special wavelength able to promote plant growth may be generated thereby.

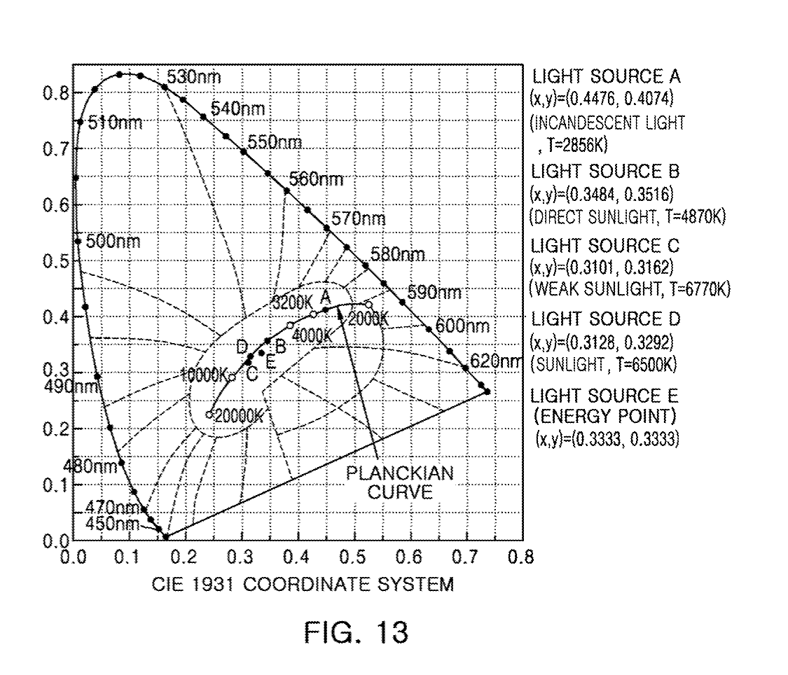

FIG. 13 is a CIE 1931 coordinate system provided to describe a wavelength conversion material which may be applied to a white light emitting device employing a semiconductor light emitting device of the above exemplary embodiment, according to an exemplary embodiment.

Referring to the CIE 1931 coordinate system illustrated in FIG. 13, white light formed by a mixture of a UV LED or a blue LED with yellow, green, and red phosphors and/or green and red LEDs may have two or more peak wavelengths and may be positioned on a line segment of the CIE 1931 coordinate system connecting (x and y) coordinates of (0.4476, 0.4074), (0.3484, 0.3516), (0.3101, 0.3162), (0.3128, 0.3292), and (0.3333, 0.3333). The white light may be positioned in a region surrounded by the aforementioned line segment and a black body radiation spectrum. The color temperature of the white light may be between 2000K and 20000K.

A variety of materials such as a phosphor and/or a quantum dot may be used as a material to convert the wavelength of light emitted from a semiconductor light emitting device.

The phosphor may have an empirical formula and a color as follows.

Oxide-based phosphor: yellow and green Y₃Al₅O₁₂:Ce, Tb₃Al₅O₁₂:Ce, and Lu₃Al₅O₁₂:Ce

Silicate-based phosphor: yellow and green (Ba,Sr)₂SiO₄:Eu, and yellow and orange (Ba,Sr)₃SiO₅:Ce

Nitride-based phosphor: green β-SiAlON:Eu, yellow La₃Si₆N₁₁:Ce, orange α-SiAlON:Eu, and red CaAlSiN₃:Eu, Sr₂Si₅N₈:Eu, SrSiAl₄N₇:Eu, SrLiAl₃N₄:Eu, and Ln₄₋ₓ (Eu_{z}M_{1-z})ₓSi_{12-y}Al_{y}O_{3+x+y}N_{18-x-y} (0.5≦x≦3, 0<z<0.3, 0<y≦4)—formula 1

In formula 1, Ln may be at least an element selected from a group consisting of a IIIa-based element and a rare-earth element, and M may be at least one element selected from a group consisting of Ca, Ba, Sr, and Mg.

Fluoride-based phosphor: KSF-based red K₂SiF₆:Mn₄⁺, K₂TiF₆:Mn₄⁺, NaYF₄:Mn₄⁺, and NaGdF₄:Mn₄⁺ (For example, a composition ratio of the Mn may be 0<z≦0.17).

The composition of the phosphor should correspond to stoichiometry, and each element thereof may be replaced with another element of the same group on the periodic table. For example, Sr may be replaced with an alkaline earth element (group II) such as Ba, Ca, Mg, and the like, and Y may be replaced with a lanthanum-based element such as Tb, Lu, Sc, Gd, and the like. In addition, an activator Eu and the like may be replaced with Ce, Tb, Pr, Er, Yb, or the like, according to a desired energy level. A single activator may be used, or a sub-activator may be additionally applied thereto for a modulation of characteristics.

In particular, each of the fluoride-based red phosphors may be coated with a fluoride not containing Mn, or may further include an organic material coated on a surface of the phosphor or a surface of the fluoride coating not containing Mn, for improvements in the reliability thereof in high temperature and high humidity environments. Such a fluoride-based red phosphor may be applied to a high-resolution TV such as an ultra-high-definition (UHD) TV, unlike other phosphors, since narrow FWHM of 40 nm or less may be implemented.

Table 2 below provides the types of phosphor categorized by use of white light emitting devices having a blue LED chip (440 to 460 nm) or a UV LED chip (380 to 440 nm).

TABLE 2

| Use | Phosphor |
|---|---|
| LED TV BLU | β-SiAlON:Eu²⁺, (Ca, Sr)AlSiN₃:Eu²⁺, |
| | La₃Si₆N₁₁:Ce³⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, |
| | NaYF₄:Mn⁴⁺, NaGdF₄:Mn⁴⁺ |
| Lighting Device | Lu₃Al₅O₁₂:Ce³⁺, Ca-α-SiAlON:Eu²⁺, |
| | La₃Si₆N₁₁:Ce³⁺, (Ca, Sr)AlSiN₃:Eu²⁺, |
| | Y₃Al₅O₁₂:Ce³⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, |
| | NaYF₄:Mn⁴⁺, NaGdF₄:Mn⁴⁺ |
| Side Viewing | Lu₃Al₅O₁₂:Ce³⁺, Ca-α-SiAlON:Eu²⁺, |
| (Mobile | La₃Si₆N₁₁:Ce³⁺, (Ca, Sr)AlSiN₃:Eu²⁺, |
| Terminal, | Y₃Al₅O₁₂:Ce³⁺, (Sr, Ba, Ca, |
| Notebook PC) | Mg)₂SiO₄:Eu²⁺, K₂SiF₆:Mn⁴⁺, SrLiAl₃N₄:Eu, |
| | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, |
| | NaYF₄:Mn⁴⁺, NaGdF₄:Mn⁴⁺ |
| Electronic | Lu₃Al₅O₁₂:Ce³⁺, Ca-α-SiAlON:Eu²⁺, |
| Component For | La₃Si₆N₁₁:Ce³⁺, (Ca, Sr)AlSiN₃:Eu²⁺, |
| Automobile | Y₃Al₅O₁₂:Ce³⁺, K₂SiF₆:Mn⁴⁺, SrLiAl₃N₄:Eu, |
| (Headlamp, etc.) | Ln₄₋ₓ(Eu_{z}M_{1-z})ₓSi_{12-y}Al_{y}O_{3+x+y}N_{18-x-y}(0.5 ≦ x ≦ 3, |
| | 0 < z < 0.3, 0 < y ≦ 4), K₂TiF₆:Mn⁴⁺, |
| | NaYF₄:Mn⁴⁺, NaGdF₄:Mn⁴⁺ |

When it comes to a wavelength converter, a wavelength conversion material such as a quantum dot may be used in place of a phosphor, or may be combined with a phosphor.

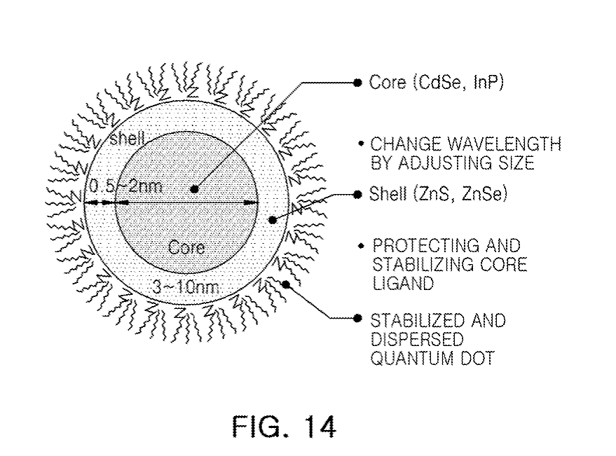

FIG. 14 is a view schematically illustrating a cross section of a quantum dot.

Referring to FIG. 14, a quantum dot (QD) may have a core-shell structure formed of a II-VI-based compound semiconductor or a III-V-based compound semiconductor. For example, the quantum dot may have a core such as CdSe, InP, and the like, and a shell such as ZnS and ZnSe. In addition, the quantum dot may include a ligand to ensure a stable core and shell. For example, a diameter of the core may range from 1 nm to 30 nm, and in detail, from 3 nm to 10 nm. A thickness of the shell may range from 0.1 nm to 20 nm, and in detail, from 0.5 nm to 2 nm.

The quantum dot may implement a range of colors depending on the size thereof, and, in particular, when the quantum dot is used as an alternative to a phosphor, the quantum dot may be used as a red or green phosphor. When the quantum dot is used, a narrow full width at half maximum (FWHM) of, for example, about 35 nm, may be implemented.

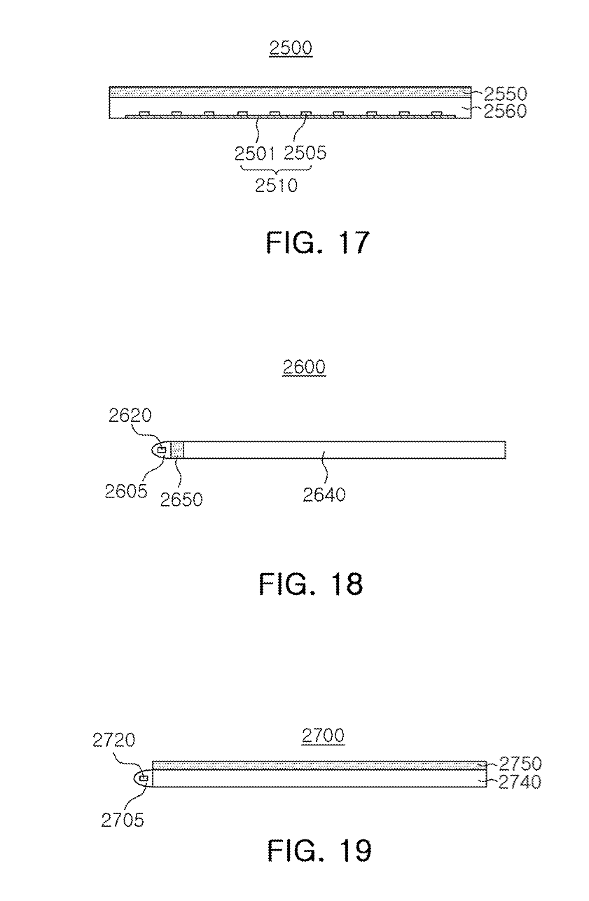

The wavelength conversion material may be contained in an encapsulant to be implemented (see FIGS. 10 and 11), or may be produced in advance in a form of a film and attached to a surface of an optical structure such as an LED chip or a light guide panel (see FIGS. 17 to 19). In the latter case, the wavelength conversion material having a constant thickness may be easily applied to a desired region.

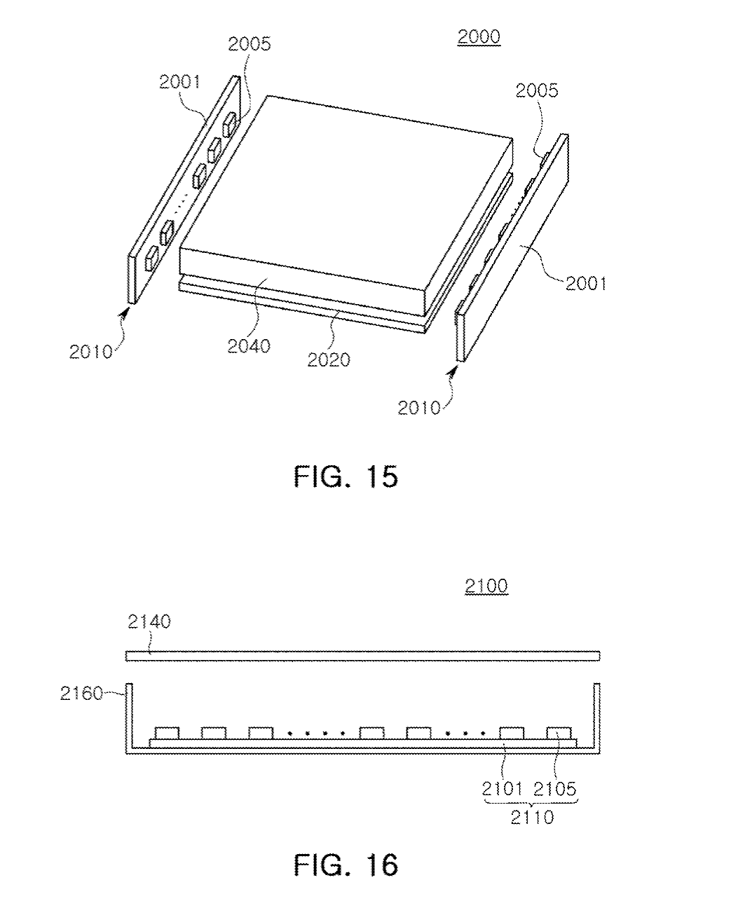

FIG. 15 is a perspective view schematically illustrating a backlight unit employing a semiconductor light emitting device of the above exemplary embodiment, according to an exemplary embodiment.

Referring to FIG. 15, a backlight unit 2000 may include a light guide panel 2040 and light source modules 2010 provided on both sides of the light guide panel 2040. In addition, the backlight unit 2000 may further include a reflection board 2020 disposed below the light guide panel 2040. The backlight unit 2000 according to the exemplary embodiment may be an edgy-type backlight unit.

The light source module 2010 may be provided on a single side of the light guide panel 2040, or provided on another side as well as both sides of the light guide panel 2040. The light source module 2010 may include a printed circuit board 2001 and a plurality of light sources 2005 mounted on an upper surface of the printed circuit board 2001.

FIG. 16 is a view illustrating a direct-type backlight unit according to an exemplary embodiment.

Referring to FIG. 16, a backlight unit 2100 may include a light diffusion panel 2140 and light source modules 2110 arranged below the light diffusion panel 2140. In addition, the backlight unit 2100 may further include a bottom case 2160 disposed below the light diffusion panel 2140 and having the light source modules 2110. According to the exemplary embodiment of the present inventive concept, the backlight unit 2100 may be a direct-type backlight unit.

The light source modules 2110 may include a printed circuit board 2101 and a plurality of light sources 2105 mounted on an upper surface of the printed circuit board 2101.

FIGS. 17 to 19 are cross-sectional views schematically illustrating backlight units employing a semiconductor light emitting device according to an exemplary embodiment. In backlight units 2500, 2600, and 2800 of FIGS. 17 to 19, wavelength conversion units 2550, 2650, and 2750 may not be disposed internally of light sources 2505, 2605, and 2705, but externally from the light sources 2505, 2605, and 2705, and internally of the backlight units 2500, 2600, and 2700 in order to convert the wavelength of light.

Referring to FIG. 17, the backlight unit 2500 may be a direct-type backlight unit including a wavelength converter 2550, light source modules 2510 arranged below the wavelength converter 2550, and a bottom case 2560 having the light source modules 2510. In addition, the light source modules 2510 may include a printed circuit board 2501 and a plurality of light sources 2505 mounted on the printed circuit board 2501. The light sources 2505 may be any one of the wavelength converters 1150a and 1150b in the light source modules 1100 and 1200 of FIGS. 10 and 11 from which a wavelength conversion material has been omitted.

In the backlight unit 2500 according to the exemplary embodiment, the wavelength converter 2550 may be disposed on the bottom case 2560. Thus, a wavelength of at least a portion of light emitted by the light source modules 2510 may be converted by the wavelength converter 2550. The wavelength converter 2550 may be manufactured as a separate film to be applied, but may also be integrally united with a light diffusion panel.

Referring to FIGS. 18 and 19, the backlight units 2600 and 2700 may be edge-type backlight units including wavelength converters 2650 and 2750, light guide panels 2640 and 2740, and reflectors 2620 and 2720 and light sources 2605 and 2705 disposed to the side of the light guide panels 2640 and 2740.

Light emitted by the light sources 2605 and 2705 may be directed to the inside of the light guide panels 2640 and 2740 by the reflectors 2620 and 2720. In the backlight unit 2600 of FIG. 18, the wavelength converter 2650 may be disposed between the light guide panel 2640 and the light source 2605. In the backlight unit 2700 of FIG. 19, the wavelength converter 2750 may be disposed on a light emission surface of the light guide panel 2740.

A general phosphor may be included in the wavelength converters 2550, 2650, and 2750 of FIGS. 17 to 19. In particular, when a quantum dot phosphor is used to supplement a weak point of a quantum dot which is not significantly resistant to heat from a light source or moisture, structures of the wavelength converters 2550, 2650, and 2750 in FIGS. 17 to 19 may be utilized.

FIG. 20 is an exploded perspective view schematically illustrating a bulb-type lamp as a lighting device employing a semiconductor light emitting device according to an exemplary embodiment.

Referring to FIG. 20, a lighting device 4200 may include a socket 4210, a power supplying unit 4220, a heat dissipation unit 4230, a light source module 4240, and an optical unit 4250. According to an exemplary embodiment, the light source module 4240 may include a light emitting device array, and the power supplying unit 4220 may include a light emitting device operating unit.

The socket 4210 may be formed so that the lighting device 2400 may replace a conventional lighting device. Power may be applied to the lighting device 4200 through the socket 4210. As illustrated, the power supplying unit 4220 may be configured of a first power supplying unit 4221 and a second power supplying unit 4222. The heat dissipation unit 4230 may include an internal heat dissipation unit 4231 and an external heat dissipation unit 4232. The internal heat dissipation unit 4231 may be directly connected to the light source module 4240 and/or the power supplying unit 4220, such that heat may be transferred to the external heat dissipation unit 4232. The optical unit 4250 may include an internal optical unit and an external optical unit, and may be configured so that light emitted by the light source module 4240 can be uniformly emitted.

The light source module 4240 may receive power from the power supplying unit 4220 to emit light to the optical unit 4250. The light source module 4240 may include one or more light emitting devices 4241, a circuit board 4242, and a controller 4243. The controller 4243 may store operating information of the light emitting devices 4241.

FIG. 21 is an exploded perspective view schematically illustrating a lamp including a communications module as a lighting device employing a semiconductor light emitting device of the above exemplary embodiment, according to an exemplary embodiment.

Referring to FIG. 21, a lighting device 4300 is different from the lighting device 4200 of FIG. 20 in that the lighting device 4300 may include a reflective panel 4310 above a light source module 4240. The reflective panel 4310 may evenly reflect light from a light source in a sideward direction and a rearward direction so as to reduce the dazzle thereof.

A communications module 4320 may be installed above the reflective panel 4310 to implement home-network communications. For example, the communications module 4320 may be provided as a wireless communications module using Zigbee, Wi-Fi, or Li-Fi. On/off switching, brightness and the like of a lighting device installed inside or outside homes may be controlled by the communications module 4320 through a smartphone or a wireless controller. In addition, electronic goods and automobile systems such as TVs, refrigerators, air conditioners, door locks, automobiles, and the like may be controlled through a Li-Fi communications module using a visible ray of the lighting device installed inside and outside homes.

The reflective panel 4310 and the communications module 4320 may be covered by a cover unit 4330.

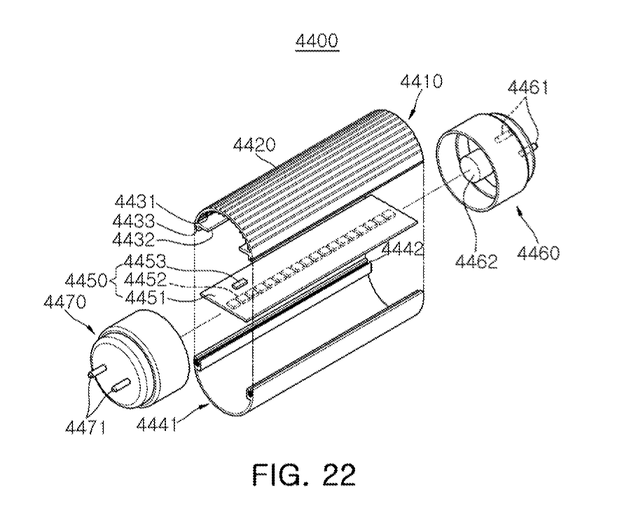

FIG. 22 is an exploded perspective view schematically illustrating a bar-type lamp as a lighting device employing a semiconductor light emitting device of the above exemplary embodiment, according to an exemplary embodiment.

In detail, a lighting device 4400 may include a heat-dissipation member 4410, a cover 4441, a light source module 4450, a first socket 4460, and a second socket 4470. A plurality of heat-dissipation fins 4420 and 4431 may be formed in a concave-convex form on an internal surface and/or an external surface of the heat-dissipation member 4410 to have various forms and intervals. A support 4432 having a form of protuberance may be formed on an internal surface of the heat-dissipation member 4410. The light source module 4450 may be fixed to the support 4432. Projections 4433 may be formed on both ends of the heat-dissipation member 4410.

A groove 4442 may be formed in the cover 4441, and the projection 4433 of the heat-dissipation member 4410 may engage with the groove 4442 in a hook-coupling structure. The positions of the groove 4442 and the projection 4433 may be interchanged with each other.

The light source module 4450 may include a light emitting device array. The light source module 4450 may include a printed circuit substrate 4451, a light source 4452, and a controller 4453. As described above, the controller 4453 may store operating information of the light source 4452. Circuit wirings for operation of the light source 4452 may be formed in the printed circuit substrate 4451. In addition, elements for the operation of the light source 4452 may be included in the printed circuit substrate 4451.

The first socket 4460 and the second socket 4470, as a pair of sockets, may engage with either ends of a cylindrical cover unit configured of the heat-dissipation member 4410 and the cover 4441. For example, the first socket 4460 may include an electrode terminal 4461 and a power-supplying device 4462, and the second socket 4470 may include a dummy terminal 4471. In addition, a light sensor and/or a communications module may be built in any one of the first socket 4460 and the second socket 4470. For example, a light sensor and/or a communications module may be built in the second socket 4470 having the dummy terminal 4471. For another example, a light sensor and/or a communications module may be built in the first socket 4460 including the electrode terminal 4461.

As set forth above, according to the above exemplary embodiments, a semiconductor light emitting device may improve light emitting efficiency by decreasing driving voltage.

While the above exemplary embodiments have been shown and described above, it will be apparent to those skilled in the art that modifications and variations could be made without departing from the scope of the inventive concept as defined by the appended claims.

What is claimed is:

1. A semiconductor light emitting device, comprising:
a support substrate;
a first layer disposed on the support substrate and applying tensile stress to the support substrate;
a bonding layer disposed on the first layer and comprising a first bonding metal and a second bonding metal;
a second layer disposed on the bonding layer and applying compressive stress to the support substrate; and
a light emitting structure disposed on the second layer and comprising a first conductivity-type semiconductor layer, an active layer, and a second conductivity-type semiconductor layer.

2. The semiconductor light emitting device of claim 1, wherein a thermal expansion coefficient of the first layer is greater than a thermal expansion coefficient of the support substrate.

3. The semiconductor light emitting device of claim 1, wherein the bonding layer comprises a first bonding layer disposed adjacent to the first layer and a second bonding layer disposed adjacent to the second layer.

4. The semiconductor light emitting device of claim 1, wherein a thermal expansion coefficient of the second layer is smaller than a thermal expansion coefficient of the first layer.

5. The semiconductor light emitting device of claim 1, wherein the first layer contains at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, and alloys thereof.

6. The semiconductor light emitting device of claim 1, wherein the second layer contains at least one selected from a group consisting of Ti, W, Ta, Ga, alloys thereof, and nitrides thereof.

7. The semiconductor light emitting device of claim 1, wherein each of the first bonding metal and the second bonding metal contains at least one selected from a group consisting of Li, Na, Mg, Hf, Ta, Cr, Mo, Mn, Fe, Ru, Ni, Cu, Zn, Pd, Pt, Ag, Au, Cd, In, Tl, Ge, Sn, Pb, Sb, Se, Al, Ti, and alloys thereof.

8. The semiconductor light emitting device of claim 1, wherein the support substrate comprises silicon,
wherein the first layer comprises aluminum (Al),
wherein the first bonding metal and the second bonding layer comprise titanium (Ti), and
wherein the second layer includes TiN.

9. The semiconductor light emitting device of claim 1, wherein a thickness of the first layer ranges from 30 nm to 500 nm.

10. The semiconductor light emitting device of claim 1, wherein a thickness of the first layer ranges from 50 nm to 200 nm.

11. The semiconductor light emitting device of claim 1, wherein a thickness of the second layer ranges from 50 nm to 500 nm.

12. The semiconductor light emitting device of claim 1, wherein a thickness of the second layer ranges from 200 nm to 300 nm.

13. The semiconductor light emitting device of claim 1, wherein the support substrate comprises silicon.

14. The semiconductor light emitting device of claim 1, wherein the first conductivity-type semiconductor layer, the second conductivity-type semiconductor layer, and the active layer are group III nitride semiconductor layers.

15. A semiconductor light emitting device, comprising:
a support substrate;
a first layer disposed on the support substrate;
a bonding layer disposed on the first layer and comprising a compound of at least two materials;
a second layer disposed on the bonding layer; and
a light emitting structure disposed on the second layer,
wherein a thermal expansion coefficient of the first layer is greater than a thermal expansion coefficient of the support substrate.

16. The semiconductor light emitting device of claim 15, wherein a thermal expansion coefficient of the second layer is smaller than the thermal expansion coefficient of the first material layer.

17. The semiconductor light emitting device of claim 15, wherein a thickness of the first layer ranges from 50 nm to 200 nm, and
wherein a thickness of the second layer ranges from 200 nm to 300 nm.

18. The semiconductor light emitting device of claim 15, further comprising a first electrode, a second electrode and an insulation layer disposed between the first and second electrodes to insulate the first and second electrodes from each other,
wherein the first and second electrodes and the insulation layer are disposed between the second layer and the light emitting structure, and
wherein the insulation layer comprise a reflect layer to reflect light emitted downwardly from the light emitting structure toward the light emitting structure.

19. The semiconductor light emitting device of claim 18, wherein the insulation layer comprises a plurality of layers having different refractive indices.

20. A semiconductor light emitting device, comprising:
a support substrate;
a first material layer disposed on the support substrate and having a thermal expansion coefficient greater than a thermal expansion coefficient of the support substrate;
a bonding layer disposed on the first material layer;
a second material layer disposed on the bonding layer and having a thermal expansion coefficient smaller than the thermal expansion coefficient of the first material layer; and
a light emitting structure disposed on the second material layer and including a first conductivity-type semiconductor layer, an active layer, and a second conductivity-type semiconductor layer.
